(19) United States
(12) Patent Application Publication
(10) Pub. No.: US 2008/0265904 A1
(43) Pub. Date: Oct. 30, 2008

(54) Trailer check

(76) Inventor: Russell Biel, Iron Ridge, WI (US)

Correspondence Address: JAMES RAY & ASSOCIATES, 2640 PITCAIRN ROAD, MONROEVILLE, PA, 15146, US

(21) Appl. No.: 12/148,641

(22) Filed: Apr. 21, 2008

Related U.S. Application Data
(60) Provisional application No. 60/914,542, filed on Apr. 27, 2007.

(51) Int. Cl. G01R 31/44

(52) U.S. Cl. 324/504

(57) ABSTRACT

An apparatus for checking lights on a tow trailer prior to connecting to a tow vehicle. The apparatus comprises a substantially hollow portable housing member. The portable member includes a turn signal switch for checking the status of such turn signals on such trailer, a brake light switch for checking the status of such brake lights, a tail light switch member for checking the status of tail lights on such trailer and a switch member for turning the portable housing member on and off. There is a power source for providing power to housing member disposed in the portable housing member. A communication means and is engageable with each of the power source, the turn signal switch, the brake light switch, the tail light switch and the switch means for providing electrical communication therein. A connection means is engageable with the communication means and is disposed on the housing member for connecting the housing member to a universal wiring harness of such trailer.

### CROSS REFERENCE TO RELATED APPLICATIONS

This application is closely related to and claims benefit from U.S. Provisional Application Ser. No. 60/914,542 filed Apr. 27, 2007

### FIELD OF THE INVENTION

The present invention relates, in general, to a device for checking the function of lights, and, more particularly, the present invention relates to a trailer check that provides consumers with a quick, easy and reliable method for testing the lights on a tow trailer.

### BACKGROUND OF THE INVENTION

Outdoor enthusiasts, travelers and vehicle towing experts who use a tow trailer to carry vehicles such as a family car, race car, all-terrain vehicle, snow mobile, boat or jet skis often test the function of the trailer lights after connecting the trailer to the tow vehicle. This safety measure requires much effort on the part of the driver as he must enter the tow vehicle to power one of the lights, then walk to the back of the trailer to ensure proper function. The driver must repeat this back and forth operation until all of the lights on the trailer are checked.

Thus, it would be advantageous if there were a unit that would allow the user to check the lights on the trailer without the need of connecting the trailer to the tow vehicle.

### SUMMARY OF THE INVENTION

In a first aspect the present invention provides an apparatus for checking lights on a tow trailer prior to connecting such tow trailer to a tow vehicle. The apparatus comprises a substantially hollow portable housing member having each of a predetermined shape and a predetermined size and formed of a predetermined material. The portable member includes a turn signal switch, a first portion of the turn signal switch disposed in the housing member and a second portion disposed on housing member for checking a status of such turn signals on such trailer; a brake light switch, a first portion of the brake light switch disposed in the housing member and a second portion disposed on the housing member for checking a status of such brake lights on such trailer;) a tail light switch, a first portion of said tail light switch disposed in the housing member and a second portion disposed on the housing member for checking a status of tail lights on such trailer; and a switch member, a first portion of the switch member disposed in the housing member and a second portion disposed on the housing member for one of turning the units on the portable housing member on and off. There is a power source disposed in the portable housing member for providing power to turn signal switch, the brake light switch, the tail light switch and the switch means. A communication means is disposed in said housing member and is engageable with each of the power source, the turn signal switch, the brake light switch, the tail light switch and the switch means for providing electrical communication therein. A connection means is engageable with the communication means and is disposed on the housing member for connecting the housing member to a universal wiring harness of such trailer.

### OBJECTS OF THE INVENTION

It is, therefore, one of the primary objects of the present invention to provide a unit that can test the function of lights on a trailer without connecting the trailer to the tow vehicle.

Another object of the present invention is to provide a unit which can test the function of tail lights, brake lights and turn signals.

Still another object of the present invention is to provide a testing unit that is portable.

Yet another object of the present invention is to provide a testing unit that is hand held.

Another object of the present invention is to provide a testing unit that is battery powered.

In addition to the various objects and advantages of the invention which have been described in some specific detail above it should be noted that various other objects and advantages of the present invention will become more readily apparent to those persons who are skilled in the relevant art from the following more detailed description, particularly when such description is taken in conjunction with the appended claims.

### BRIEF DESCRIPTION OF THE DRAWINGS

FIG. 1 is a top view of the apparatus according to an embodiment of the invention.

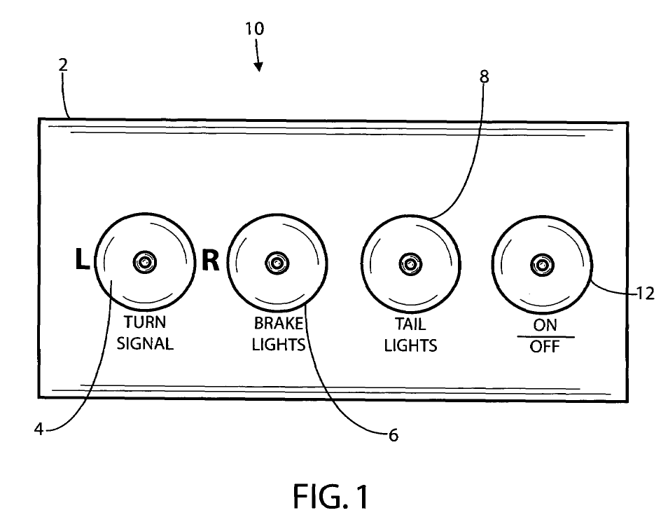

FIG. 2 is a is a side perspective view of the apparatus shown in FIG. 1.

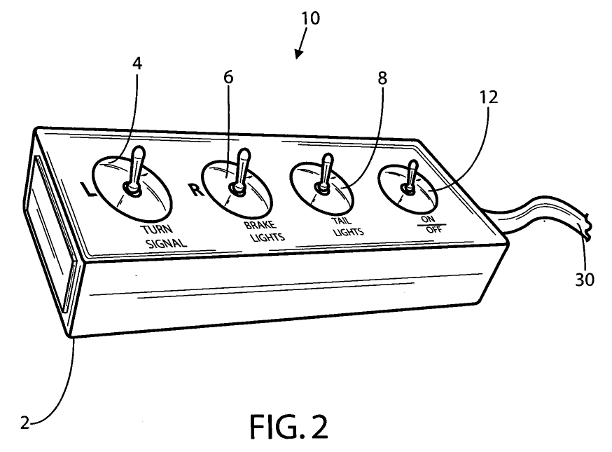

FIG. 3 is a perspective view of a tow trailer with the apparatus shown in FIGS. 1 and 2 being used to check the tail lights of the tow trailer.

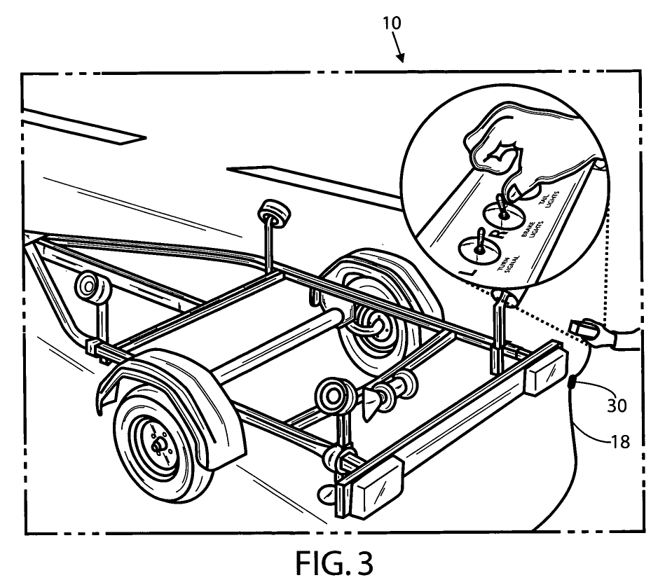

FIG. 4 is a perspective view of a tow trailer with the apparatus shown in FIGS. 1 and 2 being used to check the turn signals of the tow trailer.

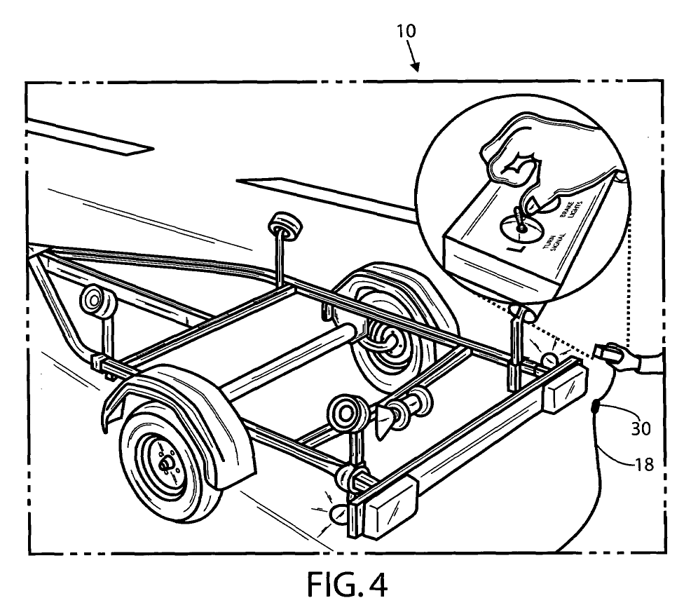

FIG. 5 is a block diagram of the communication means of the apparatus.

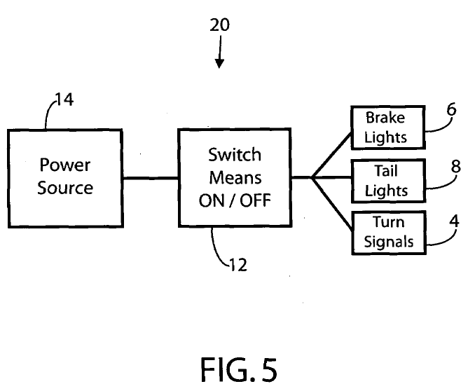

### BRIEF DESCRIPTION OF THE PRESENTLY PREFERRED AND VARIOUS ALTERNATIVE EMBODIMENTS OF THE INVENTION

Prior to proceeding with the more detailed description of the present invention it should be noted that, for the sake of clarity, identical components which have identical functions have been designated by identical reference numerals throughout the several views illustrated in the drawings.

In a first aspect the present invention provides an apparatus, generally designated 10, for checking lights on a tow trailer prior to connecting such tow trailer to a tow vehicle. The apparatus 10 comprises a substantially hollow portable housing member 2 having each of a predetermined shape and a predetermined size and formed of a predetermined material. The portable housing member 2 includes a turn signal switch 4 disposed in the housing member 2 for checking a status of such turn signals on such trailer, a brake light switch 6 disposed in the housing member 2 for checking a status of such brake lights on such trailer, a tail light switch 8 disposed in the housing member 2 for checking a status of tail lights on such trailer and a switch member 12 disposed in the housing member 2 for turning the units in the portable housing member 2 on and off. There is a power source 14 for providing power to the units disposed in the housing member 2. A communication means, generally designated 20, is disposed in said housing member 2 and is engageable with each of the power source, 14 the turn signal switch 4, the brake light switch 6, the tail light switch 8 and the switch means 12 for providing electrical communication therein. A connection means, generally designated 30, is engageable with the communication means 20 and is disposed on the housing member 2 for connecting the units in the housing member 2 to a universal wiring harness of such trailer.

Such turn signal switch 4 includes a toggle switch for testing left and right turn signals separately. The brake light switch 6 and said tail light switch 8 include a toggle switch for testing each unit separately, such switch means 12 also includes a toggle switch as well.

The predetermined size of the housing member is between about 7 and about 9 inches long and between about 2½ and about 3½ inches wide. As can be seen from the size of the portable housing member 2 such unit is a hand held unit.

The connection means 30 includes a cord 16 and a plug 18 disposed on an end of the cord 16 for connection with such universal wiring harness of such trailer.

It is presently preferred that such power source 14 includes at least one battery 22 and that such battery 22 is selected from one of a nine volt battery or a AA battery. Preferably such at least one battery includes three AA batteries. It is also within the scope of the invention that such at least one battery could be a rechargeable battery. The apparatus further includes a battery compartment disposed in a back portion of the housing member 2. There is an access cover 24 disposed on a back side of the housing member 2 for providing access to such batteries 22 in the battery compartment.

Thus, the present invention provides a hand held system designed to enable the user to test the lights of a tow trailer prior to connecting the trailer to a tow vehicle. The battery powered unit measures between about 7 and about 9 inches in length and between about 2½ and about 3½ inches wide. The unit has a plug and a cord that conveniently connects to the universal wiring component of any tow trailer. Multiple toggle switches on the apparatus will enable the unit to test the individual lights on the trailer and includes a testing switch for the left and the right turn signals as well as brake lights and tail lights. The apparatus has an on/off switch to control the power to the unit. The unit is run by batteries which can be changed by removing the access cover. The color, material style and design of the unit can vary depending on the preference of the user.

While a presently preferred embodiment and alternate embodiments of the present invention have been described in detail above, it should be understood that various other adaptations and/or modifications of the invention can be made by those persons who are particularly skilled in the art without departing from either the spirit of the invention or the scope of the appended claims.

I claim:

1. An apparatus for checking lights on a tow trailer prior to connecting such tow trailer to a tow vehicle, said apparatus comprising:
(a) a substantially hollow portable housing member having each of a predetermined shape and a predetermined size and formed of a predetermined material, said portable housing member including;
(i) a turn signal switch, a first portion of said turn signal switch disposed in said housing member and a second portion disposed on said housing member for checking a status of such turn signals on such trailer;
(ii) a brake light switch, a first portion of said brake light switch disposed in said housing member and a second portion disposed on said housing member for checking a status of such brake lights on such trailer;
(iii) a tail light switch, a first portion of said tail light switch disposed in said housing member and a second portion disposed on said housing member for checking a status of tail lights on such trailer; and
(iv) a switch member, a first portion of said switch member disposed in said housing member and a second portion disposed on said housing member for one of turning said portable member on and off;
(b) a power source disposed in said housing member for providing power to said turn signal switch, said brake light switch, said tail light switch and said switch member;
(c) a communication means disposed in said housing member and engageable with each of said power source, said turn signal switch, said brake light switch, said tail light switch and said switch means for providing electrical communication therein; and
(d) a connection means engageable with said communication means and disposed on said housing member for connecting said housing member to a universal wiring harness of such trailer.

2. The apparatus, according to claim 1, wherein said turn signal indicator includes a toggle switch for testing left and right turn signals separately.

3. The apparatus, according to claim 1, wherein each of said brake light switch and said tail light switch include a toggle switch for testing each unit separately.

4. The apparatus, according to claim 1, wherein said predetermined size of said housing member is between about 7 and about 9 inches long and between about 2½ and about 3½ inches wide.

5. The apparatus, according to claim 1, wherein said connection means includes a cord and a plug disposed on an end of said cord for connection with such universal wiring harness of such trailer.

6. The apparatus, according to claim 1, wherein said switch means includes a toggle switch.

7. The apparatus, according to claim 1, wherein said power source includes at least one battery.

8. The apparatus, according to claim 7, wherein said at least one battery is one of a nine volt battery and a AA battery.

9. The apparatus, according to claim 8, wherein said at least one battery includes three AA batteries.

10. The apparatus, according to claim 7, wherein said at least one battery is a rechargeable battery.

11. The apparatus, according to claim 1, wherein said apparatus further includes a battery compartment disposed in a portion of said housing member.

12. The apparatus, according to claim 11, wherein said housing member further includes an access cover disposed on a back side of said housing member for providing access to said battery compartment.
